(19) United States
(12) Patent Application Publication
(10) Pub. No.: US 2008/0232074 A1
(43) Pub. Date: Sep. 25, 2008

(54) Circuit Card Assembly Including Individually Testable Layers

(75) Inventors: Robert Lee Schutz, Carlsbad, CA (US); Howell B. Schwartz, San Diego, CA (US); Conrad Claire Grell, Carlsbad, CA (US); Angie Sheelan Ng, San Diego, CA (US); Gregory Scott Girkins, Oceanside, CA (US)

Correspondence Address: FISH & RICHARDSON, PC, P.O. BOX 1022, MINNEAPOLIS, MN, 55440-1022, US

(73) Assignee: VIASAT, INC., Carlsbad, CA (US)

(21) Appl. No.: 12/052,702

(22) Filed: Mar. 20, 2008

Related U.S. Application Data
(60) Provisional application No. 60/895,974, filed on Mar. 20, 2007.
(60) Provisional application No. 60/908,804, filed on Mar. 29, 2007.

(51) Int. Cl. H05K 1/18; H01L 21/66

(52) U.S. Cl. 361/761; 438/15; 257/E21.531

(57) ABSTRACT

A method for assembling a circuit card assembly includes populating a plurality of components on a top side of a component layer, performing component-level testing on at least one component of the plurality of components populated on the component layer, adhering a bonding layer to a bottom side of the component layer, the bonding layer to facilitate bonding the component layer to an interconnect layer and to provide connectivity between the plurality of components and the interconnect layer, and forming a single-sided circuit card assembly by adhering the interconnect layer to the bonding layer, the interconnect layer having a top side and a bottom side, the bonding layer adhered to the top side of the interconnect layer.

### CROSS-REFERENCE TO RELATED APPLICATIONS

This application claims priority to U.S. Provisional Application No. 60/895,974, entitled Method and Apparatus for Circuit Card Assembly, to inventors Robert Lee Schutz, Howell B. Schwartz, Conrad Claire Grell, Angie Sheelan Ng and Gregory Scott Girkins, which was filed on Mar. 20, 2007. This application also claims priority to U.S. Provisional Application No. 60/908,804, entitled Method and Apparatus for Circuit Card Assembly, to inventors Robert Lee Schutz, Howell B. Schwartz, Conrad Claire Grell, Angie Sheelan Ng and Gregory Scott Girkins, which was filed on Mar. 29, 2007. The content of the above-referenced applications are incorporated herein by reference in their entirety.

### TECHNICAL FIELD

This specification relates to circuit card assemblies (CCAs), e.g., CCAs including individually testable component layers.

### BACKGROUND

The density of components populated on boards of CCAs have increased significantly and are expected to increase further due to emerging technology. Standard tests, e.g., In Circuit Test (ICT), and the like, are used to test components on the boards in CCAs. The application of these tests and the equipment employed in such tests tend to be affected due the decreased physical accessibility of components at the board level resulting from increasing component densities. An alternative to ICT is the Flying Probe Test (FPT) which is a method to test boards with accessibility problems. The installed base of a FPT machine requires adequate clearance to nearby components for probe access. ICT tends to be a more robust test than FPT because it can apply power to devices, install flash programs, and incorporate boundary scan testing. According to an estimate by test engineering and contract manufacturers, in a typical circuit board assembly where test point access is possible, FPT is capable of achieving approximately 70% of the test coverage afforded by ICT.

A typical CCA has component densities that vary from twenty-five to forty percent. This is the ratio of raw CCA board area in to the coverage area of component packages mounted on the CCA. As systems are miniaturized and become more complex, component densities increase, eliminating the area required to support probe place for either ICT or FPT systems. Increase in component density also drive the number of layers in a CCA assembly to increase, requiring ICT and FCT probes to process increasingly complex impedances, effectively decreasing the ability of these systems to perform fault isolation to the individual component level.

As CCA assembly become smaller, multilayer assemblies combine digital, radio frequency (RF), integrated, and discrete component are often placed on the same assemblies. These components require a wide range of thermal profiles used in the CCA fabrication process. Small component packaging and higher density packaging often lead to multiple passes through component pick and place machines and wave, electron beam, or immersion soldering processes. This results in increased component stress, and component failure.

### SUMMARY

This specification describes technologies relating to a circuit card assembly including individually testable layers. In one example, a circuit card assembly includes at least two component layers that are adhered to an interconnect layer using bonding layers. Components are populated on the component layers, which are then individually tested prior to assembling the CCA. To assemble the CCA, each component layer is bonded to one side of an interconnect layer having a standard grid pattern using a bonding layer that is made using an adhesive Anisotropic Conducting Film (ACF), or other anisotropic conductive material. Thus, a double-sided CCA is assembled by bonding a first component layer on one side of an interconnect layer and by bonding a second component layer on the other side of the interconnect layer. In another example, the interconnect layer is sliced to form two portions, e.g., halves, of the interconnect layer, and components are populated on each portion of the interconnect layer. The portions are adhered to one another using a bonding layer, e.g., an ACF, or solder balls. In this manner, the components of the CCA are assembled directly onto the interconnect layer.

In one aspect, a method for assembling a circuit card assembly is described. The method includes populating a plurality of components on a top side of a component layer, performing component-level testing on at least one component of the plurality of components populated on the component layer, adhering a bonding layer to a bottom side of the component layer, the bonding layer to facilitate bonding the component layer to an interconnect layer and to provide connectivity between the plurality of components and the interconnect layer, and forming a single-sided circuit card assembly by adhering the interconnect layer to the bonding layer, the interconnect layer having a top side and a bottom side, the bonding layer adhered to the top side of the interconnect layer.

This, and other aspects can include one or more of the following features. Performing component-level testing on at least one component of the plurality of components can include accessing the at least one component from the bottom side of the component layer. The method can further include adhering another bonding layer to the bottom side of the interconnect layer, and forming a double-sided circuit card assembly by adhering another component layer having another plurality of components populated thereon to the another bonding layer. The method can further include performing functional testing on the double-sided circuit card assembly.

In another aspect, a method for assembling a circuit card assembly is described. The method includes populating a first plurality of components on a top side of a first portion of an interconnect layer, performing component-level testing on at least one component of the first plurality of components populated on the first portion, populating a second plurality of components on a top side of a second portion of the interconnect layer, performing component-level testing on at least one component of the second plurality of components populated on the second portion, and adhering a bottom side of the first portion to a bottom side of the second portion with an anisotropic conductive film to provide connectivity between the first portion, the second portion, the first plurality of components, and the second plurality of components.

This, and other aspects, can include one or more of the following features. The first portion and the second portion can be obtained by slicing the interconnect layer along a thickness of the interconnect layer. A thickness of the first portion can be half a thickness of the interconnect layer.

In another aspect, a circuit card assembly is described. The circuit card assembly includes a first component layer populated with a first plurality of components on a top side of the first component layer, a second component layer populated with a second plurality of components on a top side of the second component layer, a first anisotropic conductive film adhered to a bottom side of the first component layer, an adhering layer adhered to a bottom side of the second component layer, and an interconnect layer, the first anisotropic conductive film adhered to a top side of the interconnect layer and the adhering layer adhered to a bottom side of the interconnect layer.

This, and other aspects, can include one or more of the following features. The adhering layer can be a second anisotropic conductive film. The adhering layer can include randomly loaded conducting particles. The randomly loaded conducting particles can permit electrical conduction in one direction.

Particular implementations of the subject matter described in this specification can be implemented to realize one or more of the following advantages. Assembling components on one side of individual component layers makes available the other side for component testing. Using vias-in-pad, laser drill, and fan-out techniques, component pads assembled on the component layer can be mapped to a standard grid pattern on the opposite side, which can enable use of common bed of nail ICT and FPT test fixtures. Because individual components are not connected to nets at this stage of the assembly, each component can be accurately tested independently to determine if it is functioning properly. This can ensure that components are not damaged in the initial bonding process to the component layer assembly, or are not as-received defective, and can facilitate isolation of a broad range of fabrication and component errors. Further, mixed inner layer materials and unbalanced construction techniques can be incorporated into assembling the CCA. In implementations where a connector-interface is used, e.g., instead of the ACF, the CCA can be easily dis-assembled upon identifying a defective component, and the component can be re-worked at the same or at a later time.

In implementations where the components are attached directly to portions of the interconnect layer, the component layer can withstand larger cumulative forces and pressure, and there is only one ACF interface. Since there are multiple mid-plane test points, albeit not in one to one correspondence with the component leads, testability is still enhanced significantly. Assembling components directly onto portions of the component layer enables the portions to which components are attached to be reflowed, tested, and reworked, without the diagnostic and isolation challenges present at completed assemblies. The reliability of the system can be increased because the CCA has only one ACF layer. This implementation requires only one bonding layer which reduces the cost of CCA by improving test effectiveness and reducing scrap.

Life cycle cost benefits are also realized by separation of the CCA structure into separate component and interconnect layers. Typical CCA assemblies are updated in a products life cycle to eliminate parts obsolescence of Commercial off the Shelf (COTS) components, and/or required design modifications. Using the CCA a assembly based on individually testable layers, COTS parts changes can be made by simple redesign of the component layer, and required design modification are likely to only required the interconnect layer to be redesign. This results in simplification of the redesign process, CCA documentation, and test program generation, that reduces both risk and cost normally associated with production assemblies.

The details of one or more implementations of the disclosure are set forth in the accompanying drawings and the description below. Other features, aspects, and advantages will become apparent from the description, the drawings, and the claims.

### BRIEF DESCRIPTION OF THE DRAWINGS

FIG. 1 is an example of a schematic of individual layers of a CCA.

FIG. 2 is an example of a schematic of two CCAs connected to each other.

FIG. 3 is an example of a schematic of individual layers of two CCAs.

FIG. 4 is an example of a schematic of a CCA.

FIG. 5 is a flow chart of an example process for assembling and testing a CCA.

FIG. 6 is a flow chart of an example process for assembling and testing a CCA.

Like reference numbers and designations in the various drawings indicate like elements.

### DETAILED DESCRIPTION

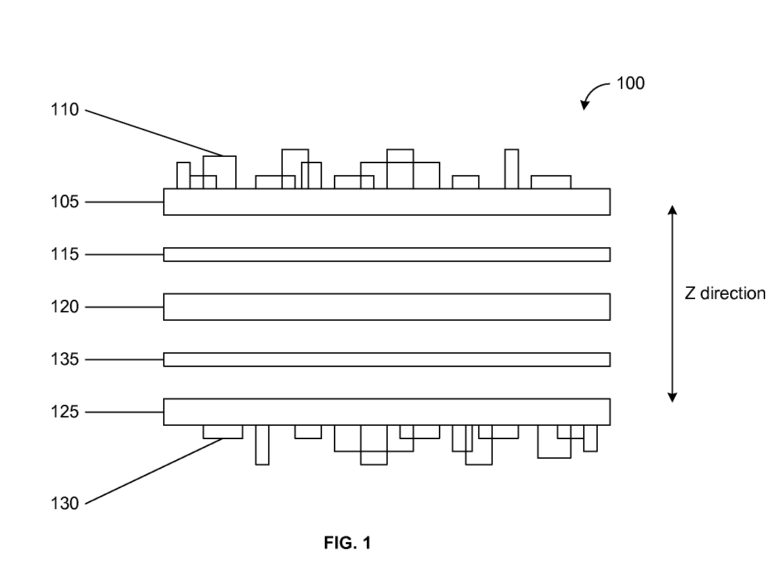

FIG. 1 depicts an example of a schematic of individual layers of a CCA 100. A single side of the CCA 100 includes multiple layers, e.g., a component layer and an interconnect layer bonded together by a bonding layer. The component layer is populated with multiple components such that component-level testing can be performed on one or more components on the component layer prior to bonding the component layer to the interconnect layer. The component layer can be bonded to the interconnect layer using an ACF that serves both, to adhere the component layer to the interconnect layer and to provide electrical conductivity in one direction, e.g., Z-direction, by virtue of the uni-directional, anisotropic conducting nature of the ACF.

In some implementations, the CCA 100 includes a first component layer 105 on which multiple components 110 are populated. The component layer can be fabricated using materials including Standard FR-4, High performance FR-4, polyimide, PTFE, or any other material known in the printed circuit board industry. The choice of the materials can depend on the type of the components that will be attached to the component layer. For example, FR-4 can be used to fabricate component layers to which digital components will be attached, and PTFE can be used to fabricate component layers to which analog components will be attached. In some implementations, a portion of the component layer can be fabricated using PTFE while the remainder of the component layer can be fabricated using FR-4 material. Because the component layer is primarily a carrier for components, and is single sided, it can be fabricated by a wide range of existing high volume commercial production systems. Because the component layer is thin and single sided, the thermal profiles are greatly simplified and component stress is significantly reduced. The first component layer 105 is populated with multiple components meaning that the multiple components are attached to a top side of the first component layer 105 using standard SMT processes. The components can include analog components, digital components, or a combination thereof. The bottom side of the first component layer 105 includes multiple planar conductive pads, e.g., square in appearance, and of Copper (Cu)/Nickel (Ni)/Gold (Au) metallization. Another example of planar conductive pads includes pads on a land grid array (LGA). In some implementations, the planar conductive pads can have any geometric shape, e.g., circular shape.

Subsequent to populating the top side of the first component layer 105, component-level testing is performed, e.g., by testing one or more components attached to the top side of the component layer 105, by accessing the components from the bottom side of the component layer 105. Individual components can be tested, e.g., using the ICT, or any other standard production testing technique. The CCA 100 includes a first bonding layer 115 to adhere the bottom side of the first component layer 105 to a top side of an interconnect layer 120. In some implementations, the interconnect layer 120 can be a standard interconnect layer with a design that can be employed regardless of the arrangement of components on the component layer 105. In some implementations, the interconnect layer 120 can be designed based on the arrangement of components on the component layer 105. The interconnect layer 120 can be made of copper or any conductive material, and can be manufactured by one of many standard printed circuit board manufacturing techniques including photo or laser imaging, chemical etch, pattern plating, lamination, mechanical or laser drilling, final route, and the like. Because the interconnect layer 120 contains no components, it can be fully tested with standard production test equipment prior to final CCA fabrication. In some implementations, the interconnect layer is an ACF material that includes semi-vertical fibers in a polymer matrix, that enable electrical conduction only in one direction, e.g., the Z-direction. In alternative implementations, the anisotropic conductive film can include gold-plated glass spheres in an elastomeric matrix.

The bonding layer 115 can include a conductive epoxy, ACF (anisotropic conductive film), or reflowed solder paste if a permanent CCA assembly is desired. The ACF can be, e.g., 3M™ Anisotropic Conductive Film offered by 3M™ (St. Paul, Minn.). Alternatively, the bonding layer 115 can be a commercially available land-grid connector. In some implementations, the bonding layer 115 can include gold plated fine wire compressed into cylindrical shapes to form fuzz button contacts. The fuzz button contacts reside within a planar non-conductive carrier that separates nearest conductors.

The assembly of the component layer 105 with the attached multiple components 110 and the interconnect layer 120 by bonding the two layers with an interconnect layer 115 forms a single-sided CCA. The single-sided CCA can be operatively coupled to another single-sided CCA formed either by the techniques described in this disclosure or by any other method of assembly to form a double-sided CCA. In some implementations, a bottom side of a second component layer 125 with multiple components attached on a top side can be adhered to the other side of the interconnect layer 120 with a bonding layer 135 made from, e.g., an ACF. The combination of the first component layer 105 and the second component layer 125 forms a double-sided CCA 100. Prior to adhering the second component layer 125 to the interconnect layer 120, most or all components attached on the top side of the second component layer 125 can be tested by standard techniques, e.g., ICT, FPT, and the like. In this manner, a CCA 100 can be assembled where each component layer is individually tested and bonded to two sides of an interconnect layer 120 using bonding layers that enable easily detaching the component layers from the interconnect layer 120. The anisotropic nature of the ACF permits electrical connectivity in only one direction, e.g., the Z-direction.

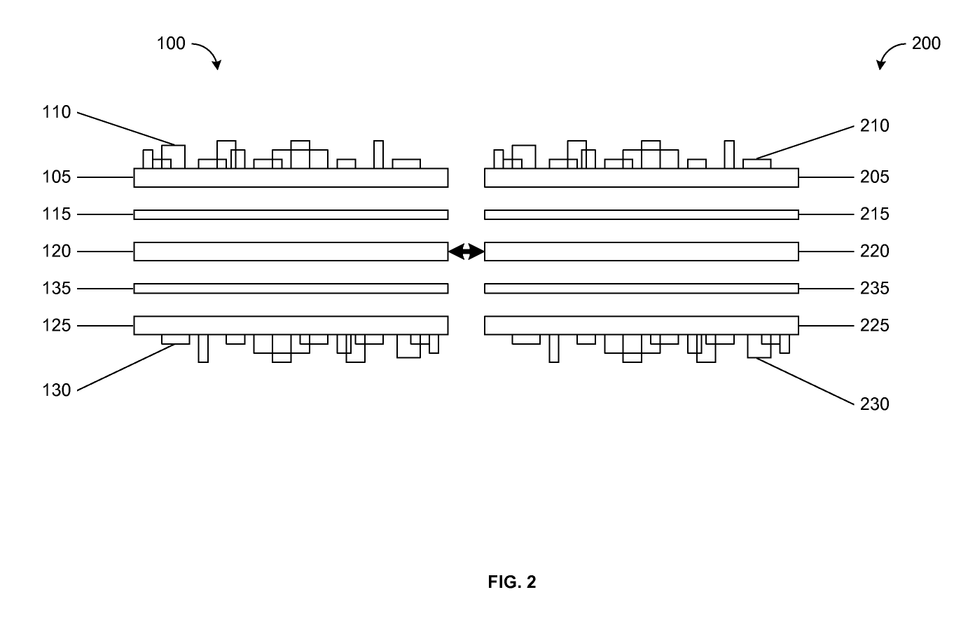

FIG. 2 is an example of a schematic of two CCAs connected to each other. In some implementations, the interconnect layer 120 of the CCA 100 can be operatively coupled to another interconnect layer 220 of a second CCA 200 that is a double-sided CCA including a component layers 205 and 225 with multiple components 210 and 230 attached thereon, respectively. The component layers 205 and 225 are adhered to the interconnect layer 220 by bonding layers 215 and 225, respectively, that can be ACFs. The components 210 and 230 on the component layers 205 and 225 are tested individually prior to assembly. Each CCA 100 and 200 can be functionally tested after assembly to ensure that the CCAs perform their intended function. In addition, the combination of the two CCAs 100 and 200 can also be tested.

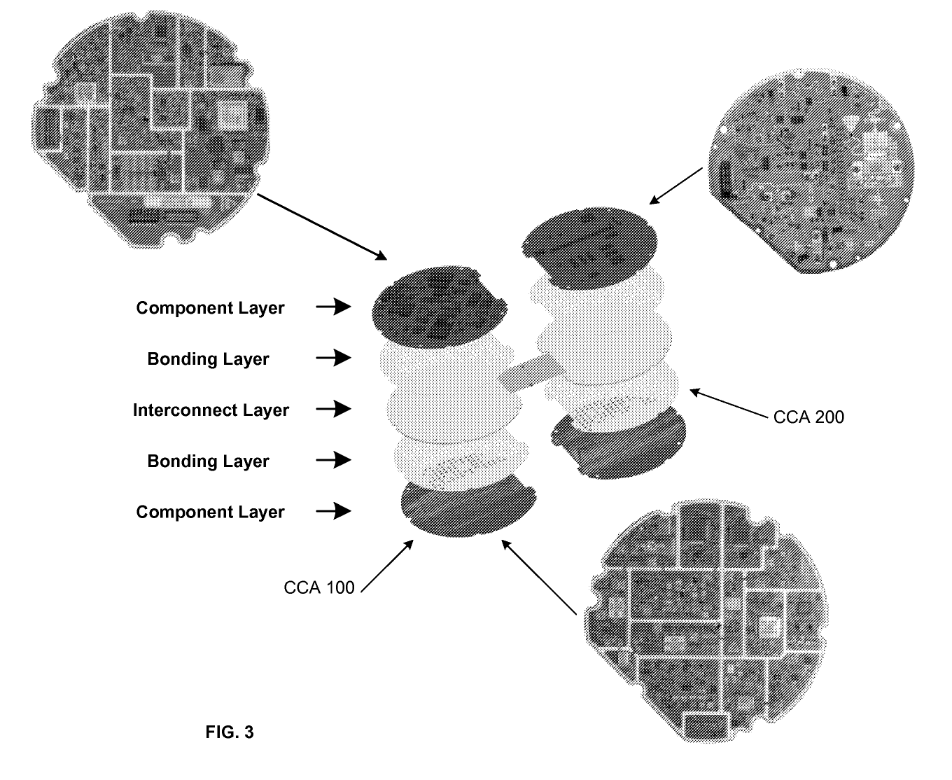

FIG. 3 is an example of a schematic of individual layers of two CCAs 100 and 200. Each CCA includes two component layers with components attached on the top side, two bonding layers to adhere each component to a side of an interconnect layer. The interconnect layers of CCA 100 and CCA 200 are operatively coupled to one another. Although the illustration in FIG. 3 depicts CCA layers that are mostly circular, the layers can be of any geometric shape.

Each side of a CCA that includes components is laid out on a three-sided circuit board. Board material and thickness is determined by specific RF impedance control requirements and component density. Components are bonded to the top side of the component layer of the CCA. Pads on the component layer of the CCA are routed through a bonding layer and then to a standardized grid pattern layout on the interconnect layer of the single-sided CCA. Very low cost commercial manufacturing techniques can be used for fabrication, and standardized fault isolation equipment can be used to validate 100% component bonding integrity. Although some interconnect between components bonded to the component layer can be made, normally the component layers simply establish a grid pattern for test. Very simple thermal profiles can be used to bond components to the component layer of the CCA, greatly reducing thermal stress failures associated with multiple bonding passes used in conventional CCA fabrication.

Routing layers are designed to provide all interconnects not made on the component layers. The number of routing layers and thickness of this assembly will be design-dependent, and can be fabricated from different material than the component layers. Top and bottom side of the routing layer of the CCA can use the identical grid pattern as the component layers. Bonding layers are designed with matching grid patterns to facilitate fusing of the component layers with the interconnect layers of the finished CCA using permanent materials such as ACF or separable materials such as fuzz buttons. In some implementations, the bonding layer can include flex-rigid-flex interconnect structure. The CCA can be assembled by fusing the component layers to the interconnect layer with the bonding layer providing insulation between component and interconnect layers. Alternatively, the CCA is assembled by using ACF films to bond a planar array of pads on the bottom side of the component layer(s) with opposing pads on the top.

In some implementations, stiffeners, typically made of rigid plastic or aluminum, are bonded or otherwise attached to the component layers of the CCA. A structural member in tension, e.g. a screw, potentially having some compliance is attached to the stiffener. By applying a mechanical load drawing these stiffeners toward each other, the “bonding layer” (or interconnect layer) is compressed and electrical continuity established. This stiffening enables easy dis-assembly of the CCA, thereby permitting post-bonding rework of the board. The need to apply high pressures orthogonal to the component layer planes is mitigated by the inclusion of stiffeners. These stiffening members can also incorporate registration features to achieve proper alignment, i.e. overlap of the planar pads being interconnected.

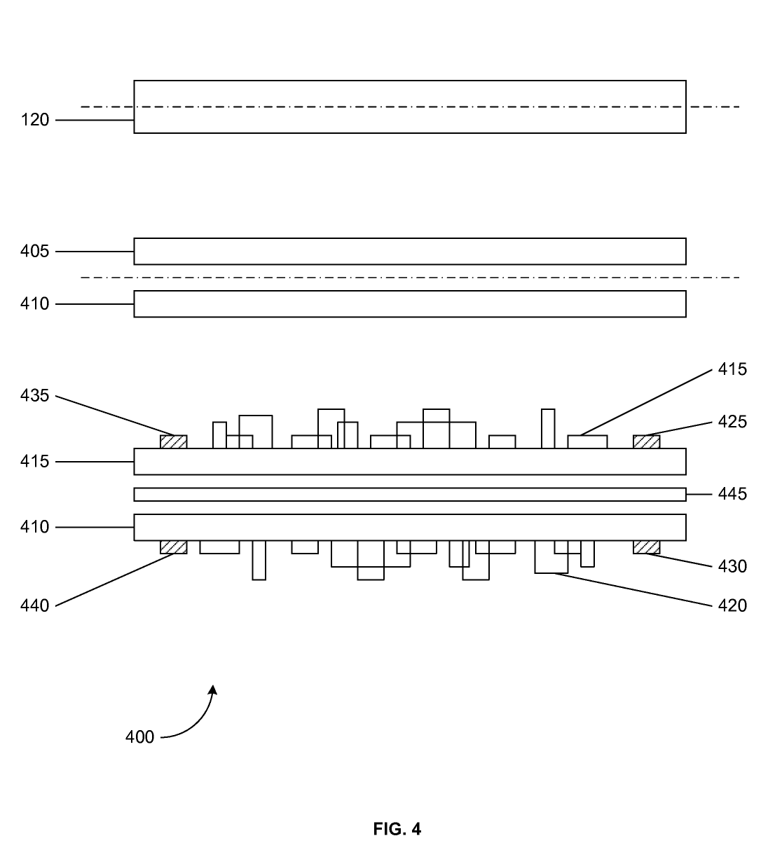

FIG. 4 is an example of a schematic of a CCA 400 including three layers. In some implementations, instead of having a separate component layer bonded to an interconnect layer 105, the interconnect layer 105 can be sliced along a horizontal plane to form two portions, e.g., interconnect layer halves 405 and 410. Then, standard processes to reflow components can be used to attach components 415 and 420 on interconnect layer halves 405 and 410, respectively. The interconnect layers 415 and 420 with the attached components can be tested using standard testing techniques. Each remaining surface of the bonding layer 445 will have a periodic area array of gold-plated planar tabs. The resulting CCA 400 will only have three boards (two populated and one ‘raw board’) to test. In some implementations, the gold pad array can employ redundancy approaches, e.g., design for reliability, for critical interconnections. In implementations where the interconnect layer 105 is cut symmetrically through it's thickness, the components can be wave-soldered to interconnect layer halves 405 and 410. Solder fill can occur for roughly half the total thickness of the interconnect layer 105. The interconnect layer halves 405 and 410 are more rigid, and better able to accommodate the pressure loading required for the lamination process. For example, activating the standard ACF material can take up to 200 psi.

In some implementations, the surface of the interconnect layer half can include stiffeners 425 and 435. Similarly, the surface of the interconnect layer half 410 can include stiffeners 430 and 440 against which the lamination load can be applied. Stiffeners 425 and 430 can be mirror images of each other, and can be glued or otherwise secured to the side of the interconnect layer halves where the components are attached. Similarly, stiffeners 435 and 440 can be mirror images of each other, and can be glued or otherwise secured to the side of the interconnect layer halves where the components are attached. In some implementations, the stiffeners can be brought together mechanically, e.g., with a clearance hole in one stiffener and a threaded insert in the opposing stiffener, accommodating a bolted interface. Features intrinsic to, or added to the stiffener, can help locate the component layers relative to the interconnect layer and relative to each other. This could also be achieved by locating pins, not shown in the figure. Although stiffeners are included in the three layer CCA illustrated in FIG. 4, stiffeners can also be included in multi-layer CCAs, e.g., CCA 100 and CCA 200.

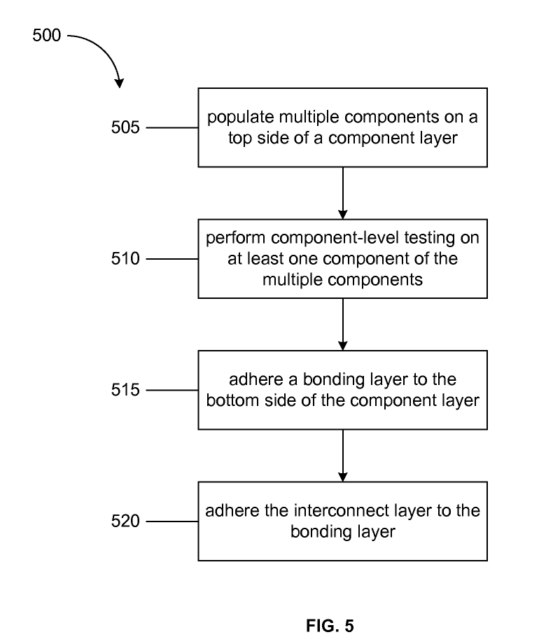

FIG. 5 is a flow chart of an example process 500 for assembling and testing a CCA. The process 500 populates multiple components on a top side of a component layer at 505. For example, multiple components can be attached to a top side of a component layer. The process 500 performs component-level testing on at least one component of the multiple components at 510. Because the components are attached to a top side of the component layer, the components are accessible from the bottom side for testing one or more components individually or as a group, e.g., in a boundary scan. The process 500 adheres a bonding layer to the bottom side of the component layer at 515. The bonding layer can be an ACF that allows electrical conductivity in only one direction, e.g., the Z-direction, by virtue of it's anisotropic conducting properties. The process 500 adheres the interconnect layer to the bonding layer at 520. For example, the interconnect layer can be made from copper, and can be bonded to the ACF film. The ACF can provide electrical connectivity between the interconnect layer and the component layer. In this manner, a component layer can be manufactured, and the individual components can be tested. Subsequently, the component layer can bonded to an interconnect layer to form a single-sided CCA. Adhering the bonding layer to the bottom side of the component layer and to the interconnect layer can be performed in a one-step operation, e.g., using a vacuum autoclave. In other implementations, the bonding layer adhering can be performed in two or more steps.

In some implementations, the process 500 includes adhering another bonding layer to the bottom side of the interconnect layer at and adhering another component layer having multiple components to the bonding layer to form a double-sided CCA. In some implementations, the process 500 includes performing functional testing on the double-sided CCA. One or more components of the component layer adhered to the other side of the interconnect layer can be tested prior to the bonding.

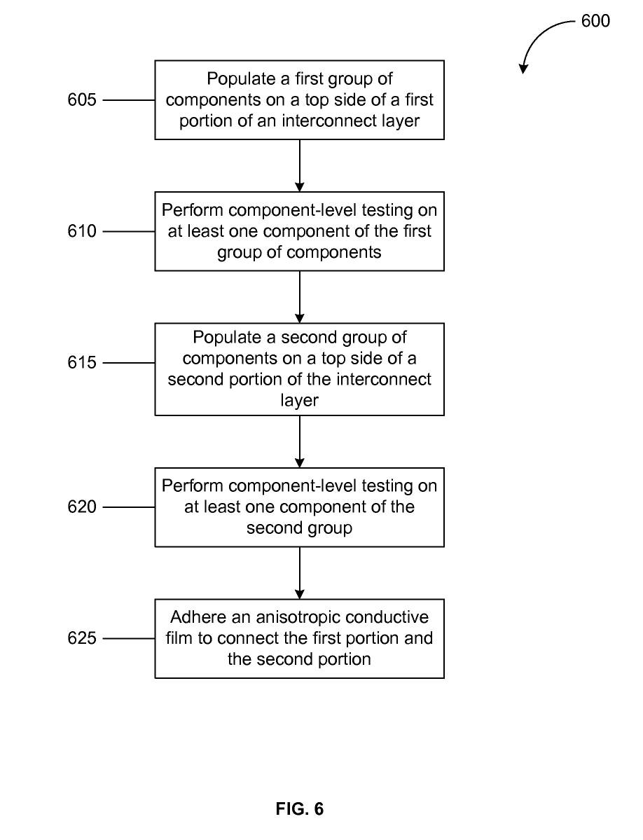

FIG. 6 depicts a flow chart of an example process 600 for assembling a circuit card assembly. The process 600 populates a first group of components on a top side of a first portion of an interconnect layer at 605. For example, an interconnect layer can be a planar surface that is rectangular in shape having a length, a width, and a thickness. In this example, the interconnect layer is oriented such that the thickness is along the Z-direction, and the length and breadth are along the XY plane. The first portion and second portion are formed by slicing the thickness of the interconnect layer. Although this example describes a rectangular surface, the interconnect layer can be a surface of any geometrical shape, e.g., circular, polygonal, and the like, having a thickness. In some implementations, the thickness of the first portion can be half the thickness of the interconnect layer. In other implementations, the first portion can be thicker than the second portion or vice versa. In some implementations, the thickness of each portion is uniform. In some implementations, the thickness of each portion is non-uniform meaning that some regions of the first portion are thicker than other regions of the first portion. The process 600 performs component-level testing on at least one component of the first group of components at 610. For example, the components attached to the top side of the first portion can be tested using ICT systems, FPT systems, and the like. The process 600 populates a second group of components on a top side of a second portion of the interconnect layer at 615. For example, one or more components can be attached to a top side of the second portion formed by slicing the interconnect layer through the thickness. The process 600 performs component-level testing on at least one component of the second group at 620. For example, the components attached to the top side of the first portion can be tested using ICT systems, FPT systems, and the like. The process 600 can adhere an anisotropic conductive film to connect the first portion and the second portion at 625. For example, the bottom side of the first portion and the bottom side of the second portion can be attached to two sides of the same ACF. The ACF can be chosen to permit electrical conduction only in one direction, namely, the direction leading from the bottom side of the first portion to the bottom side of the second portion. In this manner, a double-sided circuit board assembly can be prepared using only one ACF layer, where some or all components can be tested prior to card assembly.

Separating interconnect layers from the component layers allows re-targeting the various footprints of the components on the component layer on the grid pattern. This allows using the same test equipment for multiple component layers rather than having to develop custom test equipment and fixtures for each component layer. Such a generic test fixture that can be used for testing layers of multiple CCA's can be programmed to support a range of CCA layers. Testing components on the component layer prior to assembling the CCA alleviates the difficulty of testing individual components after the layers are assembled that arises because of the complex impedances developed upon assembly. For example, a filter network may have a wide range of parameters affecting the impedance. Assembling individual layers allows testing the components of the filter network at very fine fidelity, e.g., as low as 2%. The components of a filter network can be tested individually, e.g., the resistance of a resistor, the capacitance of a capacitor, and the like, can be tested, as opposed to testing the entire network as a filter. This allows reducing the range of allowable tolerances of each component, and in the process, allows reducing the tolerance of the filter network itself. This concept of testing can be extended to any system including components attached to the component layer.

Using a standard interconnect layer allows changing components and component layout on the component layer without changing the interconnect layer to account for the new component layout. The system and techniques described in this disclosure can be applied in technological areas that require building dense, complex logic structures and/or RF structures where the nature of integration and reduction in size of circuits may affect the ability to get test probes to each component. In the techniques described in this disclosure, because the components assembled on the top side of a component layer are accessible from the bottom side, the process of testing each component, if need be, using standard test probes is simplified. Another application of the techniques described herein is in boundary scanning multiple digital components attached to a component layer where at least all of the components, that are boundary scannable, are accessible for testing by a single signal transmitted along a scan chain.

While this specification contains many specifics, these should not be construed as limitations on the scope of the disclosure or of what may be claimed, but rather as descriptions of features specific to particular implementations of the disclosure. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be populated together in a single software product or packaged into multiple software products.

Thus, particular implementations have been described. Other implementations are within the scope of the following claims. In some implementations, a material such as FaradFlex® offered by Mitsui Kinzoku Corporate Group (Hoosick Falls, N.Y.), a buried capacitance material which puts a capacitor plane inside the CCA to reduce the overall impedance of the power distribution system and freeing up surface area, can be incorporated such that the material is potentially laminated at the mid-plane or elsewhere. In some implementations, light pipes and fiber optics communication systems can be employed in order to improve the signal to noise ratio. For example, a distributed even planar layer containing several pipes (bundle) or a single pipe in which data can translate to various transceivers can be used. For a single pipe, accessible spots can be used to communicate to the other peripherals. By having a layer of the laminated structure include a light distribution plane, light can be modulated to send data, reducing the amount of copper and eliminating ground current noise. An integrated transmitter capable of transmitting signals through the data medium can be attached to a mounted circuit component. Each of the complex components can optically receive the digital signal through the conceived planar layer resulting in communication between components by using the transmitters without the need for interconnecting circuitry.

In some implementations, by using appropriate pad spacing, e.g., 0.040″ pads on 0.050″ centers, for the interconnected pad arrays, can result in more pads than necessary being available. The additional pads can selectively be used to introduce redundancy to critical interconnections. For example, if there is no redundancy and the failure rate per interconnection is 0.01%, then putting the pads in parallel redundancy reduces the failure rate to 0.000001%. This in turn can sizably improve system reliability. Any type of bonding material can be used for the bonding described herein. These include ACF films, conductive adhesives, solder balls or solder columns, “fuzz buttons” for separable systems, etc. If solder balls or films are used, after the adhering process an “underfill” material could be injected between the boards or alternatively, an “in process” underfill material can be used. “Underfill” here refers to a material, typically of low viscosity, that fills the region around the solder ball and mitigates the effect of thermal cycling on solder-joint reliability.

In some implementations, the stiffeners can be designed as honeycomb structure with cutouts to bypass components mounted on the component layer, and can either be integral with the product board, or incorporated as temporary and board-specific fixtures in the lamination tooling. In some implementations, the interconnect layers for critical components, such as capacitors in parallel, can be attached in the opposite half of the printed circuit board. This avoids the possibility of there not being a one-to-one correspondence between component terminals and the planar array on the split interconnect layer due to the potential inability to isolate the out-of-tolerance condition. In some implementations, a heat pipe or other cooling schemes can be incorporated into the CCA.

In some implementations, low-profile layer-to-layer connectors are used to achieve interconnection between functional circuit blocks with an aim to map areas on each of the boards such that components requiring a high degree of connectivity are located on the same layer. This reduces a need for interconnections between the layers. The top layer can be digital-component intensive, and the bottom layer can be analog-component dedicated. This would still achieve the objective of allowing both board planes to be independently testable at high coverage, while at the same time evoking new application of commercially available connector technology. This could also evoke fiber optic and distributed capacitance methods as discussed above. Further, in this implementation, the connector attachment pads can be jointly interconnected to the standard square grid, thereby enhancing board of nails testability.

In some implementations, additional, redundant components can be attached to the component layer, and these redundant components can be tested individually. Upon detecting that the failure of a component on the component layer during testing, the circuitry on the component layer can be re-wired to include the redundant components. Because the interconnect layer has a standardized pattern, and because connections to the redundant components are accounted for in the interconnect layer, the need to design a new component layer or a new interconnect layer is negated. In some implementations, redundant interconnections can also be incorporated into the interconnect layer to account so that failed or poor connections can be replaced.

What is claimed is:

1. A method for assembling a circuit card assembly, the method comprising:
populating a plurality of components on a top side of a component layer;
performing component-level testing on at least one component of the plurality of components populated on the component layer;
adhering a bonding layer to a bottom side of the component layer, the bonding layer to facilitate bonding the component layer to an interconnect layer and to provide connectivity between the plurality of components and the interconnect layer; and
forming a single-sided circuit card assembly by adhering the interconnect layer to the bonding layer, the interconnect layer having a top side and a bottom side, the bonding layer adhered to the top side of the interconnect layer.

2. The method of claim 1, wherein performing component-level testing on at least one component of the plurality of components comprises accessing the at least one component from the bottom side of the component layer.

3. The method of claim 1, further comprising:
adhering another bonding layer to the bottom side of the interconnect layer; and
forming a double-sided circuit card assembly by adhering another component layer having another plurality of components populated thereon to the another bonding layer.

4. The method of claim 3, further comprising performing functional testing on the double-sided circuit card assembly.

5. The method of claim 3, further comprising testing at least one of the another plurality of components prior to adhering the another bonding layer to the another component layer.

6. The method of claim 1, wherein performing component-level testing comprises testing all components of the plurality of components populated on the component layer.

7. The method of claim 6, wherein the at least one component is tested using a Flying Probe Test system.

8. The method of claim 1, wherein the bonding layer is an anisotropic conductive film.

9. The method of claim 1, wherein the bonding layer includes an adhesive.

10. A method for assembling a circuit card assembly, the method comprising:
populating a first plurality of components on a top side of a first portion of an interconnect layer;
performing component-level testing on at least one component of the first plurality of components populated on the first portion;
populating a second plurality of components on a top side of a second portion of the interconnect layer;
performing component-level testing on at least one component of the second plurality of components populated on the second portion; and
adhering a bottom side of the first portion to a bottom side of the second portion with an anisotropic conductive film to provide connectivity between the first portion, the second portion, the first plurality of components, and the second plurality of components.

11. The method of claim 10, wherein the first portion and the second portion are obtained by slicing the interconnect layer along a thickness of the interconnect layer.

12. The method of claim 10, wherein a thickness of the first portion is half a thickness of the interconnect layer.

13. A circuit card assembly comprising:
a first component layer populated with a first plurality of components on a top side of the first component layer;
a second component layer populated with a second plurality of components on a top side of the second component layer;
a first anisotropic conductive film adhered to a bottom side of the first component layer;
an adhering layer adhered to a bottom side of the second component layer; and
an interconnect layer, the first anisotropic conductive film adhered to a top side of the interconnect layer and the adhering layer adhered to a bottom side of the interconnect layer.

14. The circuit card assembly of claim 13, wherein the adhering layer is a second anisotropic conductive film.

15. The circuit card assembly of claim 13, wherein the adhering layer includes randomly loaded conducting particles.

16. The circuit card assembly of claim 15, wherein the randomly loaded conducting particles permit electrical conduction in one direction.

17. The circuit card assembly of claim 13, wherein the adhering layer includes a thermoplastic.
